(19) United States
(12) Patent Application Publication
(10) Pub. No.: US 2021/0375613 A1
(43) Pub. Date: Dec. 2, 2021

(54) SiC WAFER MANUFACTURING METHOD

(71) Applicant: Toyo Tanso Co., Ltd., Osaka (JP)

(72) Inventors: Norihito YABUKI, Kagawa (JP); Yuji NAKASHIMA, Kagawa (JP); Takuya SAKAGUCHI, Kagawa (JP); Satoru NOGAMI, Kagawa (JP); Makoto KITABATAKE, Kagawa (JP)

(73) Assignee: Toyo Tanso Co., Ltd., Osaka (JP)

(21) Appl. No.: 17/262,387

(22) PCT Filed: Jul. 25, 2019
(86) PCT No.: PCT/JP2019/029161

§ 371 Date: Aug. 23, 2021

(30) Foreign Application Priority Data
Jul. 25, 2018 (JP) 2018-139347

(51) Int. Cl. H01L 21/02; C30B 33/12; C30B 29/36; B24B 37/04

(52) U.S. Cl. CPC H01L 21/02019; C30B 33/12; B24B 37/044; H01L 21/02013; C30B 29/36

(57) ABSTRACT

In a method for manufacturing an SiC wafer, a work-affected layer removal step of removing a work-affected layer generated in a surface and inside of an SiC wafer is performed, so that the SiC wafer from which the work-affected layer is at least partially removed is manufactured. In the work-affected layer removal step, the SiC wafer having undergone a polishing step is etched with an etching amount of 10 μm or less by being heated under Si vapor pressure so that the work-affected layer is removed. In the polishing step, an oxidizer is used to produce a reaction product in the SiC wafer while abrasive grains are used to remove the reaction product. In the SiC wafer having undergone the polishing step, an internal stress caused by the work-affected layer is present at a location inner than the work-affected layer, and an internal stress of the SiC wafer is reduced by removing the work-affected layer in the work-affected layer removal step.

### TECHNICAL FIELD

The present invention mainly relates to a method for manufacturing an SiC wafer from which a work-affected layer is removed.

### BACKGROUND ART

According to Patent Literature 1 (PTL 1), subjecting an SiC wafer to mechanical polishing, for example, causes polishing flaws on a surface of the SiC wafer, and also causes latent damage inside the SiC wafer. PTL 1 also shows a method for removing latent damage by heating an SiC wafer under Si vapor pressure and thereby etching a surface of the SiC wafer.

### CITATION LIST

### Patent Literature

PTL 1: WO2015/151413

### SUMMARY OF INVENTION

### Technical Problem

In a case of removing a work-affected layer containing, for example, latent damage by means of etching as shown in PTL 1, it is preferable that the work-affected layer be removed with a small etching amount. This is because a smaller etching amount can shorten time required for the removal of the work-affected layer, can efficiently use monocrystalline SiC as a material, and moreover can reduce deterioration of a processing apparatus that performs the etching.

The present invention has been made in view of the circumstances described above, and a primary object of the present invention is to provide a method for manufacturing an SiC wafer, the method being capable of sufficiently removing a work-affected layer with a small etching amount.

### Solution to Problem and Advantageous Effects

The problem to be solved by the present invention is as above. The following describes solutions to the problem as well as advantageous effects thereof.

An aspect of the present invention provides a method for manufacturing an SiC wafer as follows. The method for manufacturing an SiC wafer includes a work-affected layer removal step of removing a work-affected layer generated in a surface and inside of an SiC wafer, to manufacture an SiC wafer from which the work-affected layer is at least partially removed. In the work-affected layer removal step, a post-polishing wafer is etched with an etching amount of 10 μm or less by being heated under Si vapor pressure so that the work-affected layer is removed, the post-polishing wafer being a wafer whose surface has been polished by using an oxidizer to produce a reaction product in the SiC wafer while using abrasive grains to remove the reaction product. In the post-polishing wafer, a stress caused by the work-affected layer is present at a location inner than the work-affected layer, and an internal stress of the SiC wafer is reduced by removing the work-affected layer in the work-affected layer removal step.

The reaction product, which is relatively soft, produced by using the oxidizer is removed by using the abrasive grains. This makes a work-affected layer less likely to be generated, as compared to when another polishing method is adopted. Accordingly, even though the etching amount is 10 μm or less, the work-affected layer can be removed sufficiently. In addition, the etching amount is smaller than conventional, which can shorten time required for the processing, and also can reduce a load on a processing apparatus.

In the method for manufacturing an SiC wafer, it is preferable that the surface of the post-polishing wafer has an arithmetic surface roughness (Ra) of 0.7 nm or less.

As the surface roughness of the post-polishing water is lower, a work-affected layer containing scratches, for example, is less likely to be generated after the work-affected layer removal step which will be performed subsequently, and thus an SiC wafer with a higher quality can be manufactured.

In the method for manufacturing an SiC wafer, it is preferable that in the work-affected layer removal step, the etching is performed with an etching amount of 20 nm or more.

This allows the work-affected layer contained in the post-polishing wafer to be removed sufficiently.

The method for manufacturing an SiC wafer is preferably as follows. The method for manufacturing an SiC wafer further includes a polishing step that is performed before the work-affected layer removal step. In the polishing step, the oxidizer is used to produce the reaction product in the SiC wafer while the abrasive grains are used to remove the reaction product, so that a surface is polished.

The reaction product, which is relatively soft, produced by using the oxidizer is removed by using the abrasive grains. This makes a work-affected layer less likely to be generated in the SiC wafer, as compared to when another polishing method is adopted. Accordingly, the work-affected layer can be removed easily.

In the method for manufacturing an SiC wafer, it is preferable that in the polishing step, the abrasive grains having a lower hardness than SiC are used for polishing.

Using the above-described abrasive grains can suppress damaging to an Sic portion while removing the reaction product, because the reaction product produced by using the oxidizer has a lower hardness than SiC.

### BRIEF DESCRIPTION OF DRAWINGS

FIG 1 A diagram illustrating an outline of a high-temperature vacuum furnace that is used for Si vapor pressure etching according to an embodiment of the present invention

FIG 2 A diagram schematically showing steps of manufacturing an SiC wafer according to the embodiment

FIG 3 A perspective view showing a configuration of a polishing apparatus that is used in a polishing step

FIG 4 A diagram illustrating that a work-affected layer and a stress layer that are present in an SiC wafer after the polishing step are removed by a work-affected layer removal step

FIG 5 A diagram showing scratch maps related to an SiC wafer after the polishing step and the SiC wafer after the work-affected layer removal step

FIG 6 A diagram showing scratch maps related to SiC wafers that were etched with different etching amounts in the work-affected layer removal step

FIG 7 A diagram for comparison of SiC wafers in terms of the surface roughness after the polishing step and the scratch amount after the work-affected layer removal step

### DESCRIPTION OF EMBODIMENTS

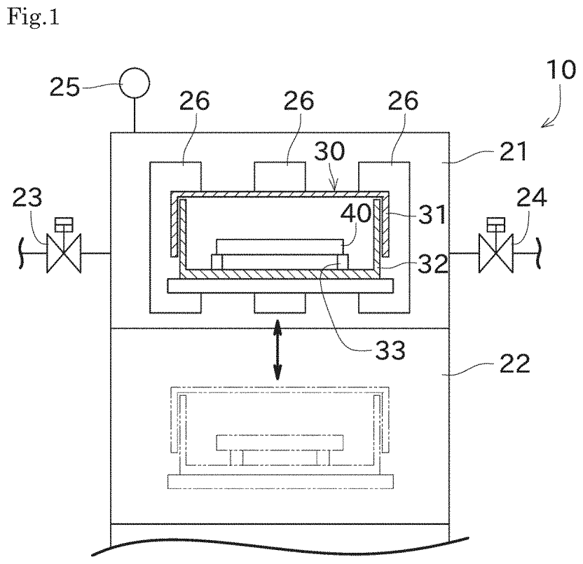

Hereinafter, an embodiment of the present invention will be described with reference to the drawings. First, referring to FIG. 1, a high-temperature vacuum furnace 10 that is used in, for example, a method for manufacturing an SiC wafer according to the embodiment will be described.

As shown in FIG. 1, the high-temperature vacuum furnace 10 includes a main heating chamber 21 and a preheating chamber 22. The main heating chamber 21 is capable of heating an SiC wafer 40 (monocrystalline SiC substrate) up to a temperature of 1000° C. or more and 2300° C. or less. The SiC wafer 40 is, at least in its surface, made of monocrystalline SiC (such as 4H-SiC or 6H-SiC). The preheating chamber 22 provides a space where the Sic wafer 40 is preheated before being heated in the main heating chamber 21.

Connected to the main heating chamber 21 are a vacuum creating valve 23, an inert gas injection valve 24, and a vacuum gauge 25. The vacuum creating valve 23 is capable of adjusting the degree of vacuum in the main heating chamber 21. The inert gas injection valve 24 is capable of adjusting the pressure of an inert gas in the main heating chamber 21. In this embodiment, the inert gas is a gas of a group 18 element (rare gas element) such as Ar, which is a gas having a poor reactivity with solid SiC, and is a gas excluding a nitrogen gas. The vacuum gauge 25 is capable of measuring the degree of vacuum in the main heating chamber 21.

Heaters 26 are disposed in the main heating chamber 21. A heat reflecting metal plate (not shown) is fixed to a side wall and a ceiling of the main heating chamber 21, and the heat reflecting metal plate is configured to reflect heat of the heaters 26 toward a central region of the main heating chamber 21. This enables the SiC wafer 40 to be heated strongly and uniformly, so that its temperature can rise up to 1000° C. or more and 2300° C. or less. Examples of the heater 26 may include a heater of resistance heating type and a heater of high frequency induction heating type.

The high-temperature vacuum furnace 10 heats the SiC wafer 40 received in a crucible (receiving container) 30. The receiving container 30, which is placed on an appropriate support base, etc., is configured such that as the support base moves, the receiving container 30 moves at least from the preheating chamber to the main heating chamber. The receiving container 30 includes an upper container 31 and a lower container 32 which are fittable to each other. The lower container 32 of the receiving container 30 has a support part 33 capable of supporting the SiC wafer 40 such that both a principal surface and a backside surface of the SiC wafer 40 are exposed. The principal surface of the SiC wafer 40 is an Si surface, which is (0001) plane if expressed in the sense of the crystal plane. The backside surface of the SiC wafer 40 is a C surface, which is (000-1) plane if expressed in the sense of the crystal plane. The SiC wafer 40 may have an off-angle relative to the Si surface and the C surface, and may have the C surface serve as a principal surface. The principal surface is one of the two surfaces (top and bottom surfaces in FIG. 1) having the largest area among the surfaces of the SiC wafer 40, and is a surface on which an epitaxial layer will be formed in a later step. The backside surface is a surface on the side opposite to the principal surface.

The receiving container 30 has an internal space where the SiC wafer 40 is received, and a portion of the receiving container 30 serving as wall surfaces (an upper surface, a side surface, and a lower surface) defining the internal space is made of a tantalum layer (Ta), a tantalum carbide layer (TaC and Ta₂C), and a tantalum silicide layer (TaSi₂ or Ta₅Si₃, etc.) arranged in this order from the outer side to the internal space side.

The tantalum silicide layer, when heated, supplies Si to the internal space of the receiving container 30. Since the receiving container 30 includes the tantalum layer and the tantalum carbide layer, C vapor existing in the surroundings can be taken in. As a result, a highly pure Si atmosphere can be created inside the internal space in heating. Here, it is possible to arrange an Si source as exemplified by solid Si in the internal space, instead of providing the tantalum silicide layer. In such a configuration, the solid Si sublimates in heating, so that the inside of the internal space comes under a highly pure Si vapor pressure.

To heat the SiC wafer 40, firstly, the receiving container 30 is disposed in the preheating chamber 22 of the high-temperature vacuum furnace 10 as illustrated with the dot-dash lines in FIG. 1, and is preheated at an appropriate temperature (e.g., about 800° C.). Then, the receiving container 30 is moved to the main heating chamber 21 whose temperature has been preliminarily raised to a preset temperature (e.g., about 1800° C.). Then, the SiC wafer 40 is heated with adjustment of the pressure, etc. The preheating may be omitted.

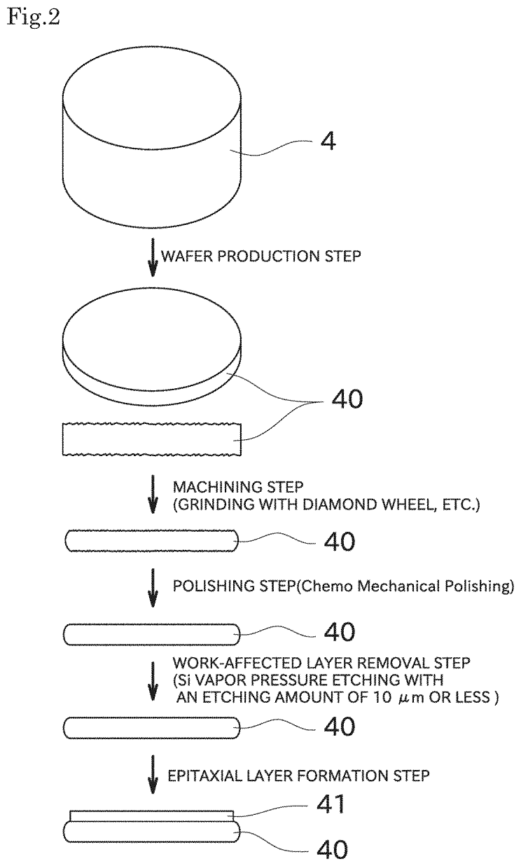

Steps of manufacturing the SiC wafer 40 (especially the SiC wafer 40 on which an epitaxial layer is formed) of this embodiment will now be described with reference to FIG. 2. FIG. 2 is a diagram schematically showing steps of manufacturing the SiC wafer 40 according to this embodiment.

The SiC wafer 40 is produced from an ingot 4. The ingot 4 is a mass of monocrystalline SiC produced through a known sublimation process or solution growth process, etc. As shown in FIG. 2, the SiC ingot 4 is cut with predetermined intervals by using cutting means such as a diamond wire, so that a plurality of SiC wafers 40 are produced from the ingot 4 (wafer production step). It may be possible that the SiC wafer 40 is produced through another method. For example, it is possible to form a damage layer by applying a laser radiation to the ingot 4 and then taking out a wafer-shaped portion. It is also possible that a monocrystalline SiC substrate and a polycrystalline SiC substrate obtained from an ingot, etc. are laminated to each other, which is then subjected to a process such as a peeling process if necessary, so that an SiC wafer containing monocrystalline SiC at least in its surface can be produced. The SiC wafer 40 in a state after being produced from the ingot 4 and before being subjected to a machining step, which will be described below, can be referred to as an as-sliced wafer or a pre-process wafer.

Then, the SiC water 40 is subjected to the machining step. In the machining step, for example, a process (grinding) for mechanically scraping at least the principal surface of the SiC wafer 40 is performed by using a diamond wheel or the like. The process in the machining step is for the purpose of obtaining a target thickness of the SiC wafer 40. The machining step may be divided into two or more stages where tools having abrasive grains with different grain sizes are used. The SiC wafer 40 in a state after the machining and before a polishing step, which will be described below, can be referred to as a post-grinding SiC wafer.

Then, the SiC wafer 40 is subjected to the polishing step. Conventionally, after the machining step, the SiC wafer 40 undergoes chemical mechanical polishing using a predetermined slurry. The slurry is a mixture of a chemical liquid and abrasive grains. In this embodiment as well, polishing is performed by using a slurry. The slurry used in this embodiment contains a chemical liquid that exhibits an oxidizing effect (details will be given below). Polishing of this type is called chemo mechanical polishing.

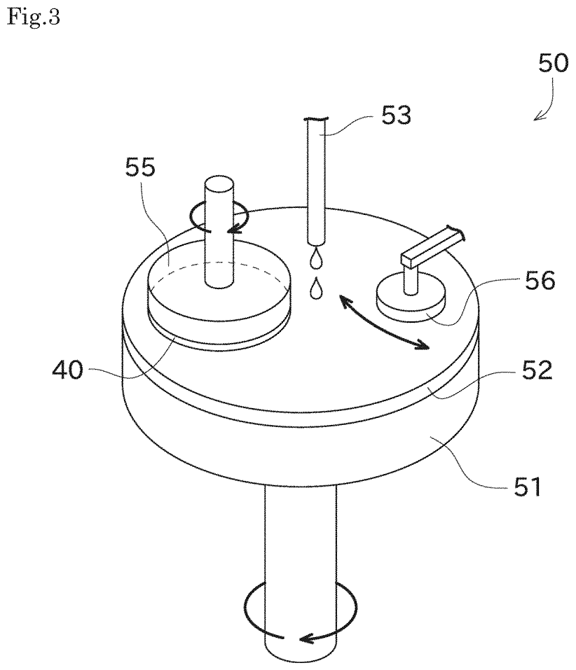

In the following, the polishing step of this embodiment will be described in detail with reference to FIG. 3, which is a perspective view showing a configuration of a polishing apparatus 50 used in the polishing step.

As shown in FIG. 3, the polishing apparatus 50 includes a rotating support base 51, a polishing pad 52, a slurry supply tube 53, a wafer carrier 55, and a pad conditioner 56. The polishing apparatus 50 is not limited to the one illustrated in FIG. 3 and the following description. Shapes and configurations of parts of the polishing apparatus 50 may be different from those of this embodiment.

The rotating support base 51 is a disk-shaped member, which is configured to be rotatable about the axial direction as shown in FIG. 3. The polishing pad 52 having a disk-like shape and made of, for example, a urethane foam or another material is attached to a top surface of the rotating support base 51. The slurry supply tube 53 supplies a slurry onto the polishing pad 52. Details and effects of the slurry used in this embodiment will be described later.

The wafer carrier 55 is configured such that the SiC wafer 40 can be fixed to a bottom surface of the wafer carrier 55. The wafer carrier 55 presses the principal surface (polishing target surface) of the SiC wafer 40 fixed to the bottom surface of the wafer carrier 55 against the polishing pad 52. The wafer carrier 55 is capable of rotating about the axial direction as shown in FIG. 3, while pressing the SiC wafer 40 against the polishing pad 52. The center of rotation of the rotating support base 51 is different from the center of rotation of the wafer carrier 55. This configuration allows the slurry to act on the SiC wafer 40. As the polishing advances, fine pores of the polishing pad 52 are clogged with processing debris, reaction products, and the like. The pad conditioner 56 removes the clogging by scraping the surface of the polishing pad 52.

The slurry of this embodiment contains an oxidizer for oxidizing the SiC wafer 40. As mentioned above, the slurry includes the chemical liquid and the abrasive grains. The slurry is, for example, an alumina slurry, a cerium-oxide slurry, a manganese-oxide slurry, an iron-oxide slurry, or the like. The chemical liquid is, for example, potassium permanganate, a hydrogen peroxide solution, ammonium peroxide, or the like. The abrasive grains are, for example, alumina, cerium oxide, manganese oxide, iron oxide, or the like. In the slurry of this embodiment, the foregoing chemical liquid functions as the oxidizer.

Oxidation of the SiC wafer 40 by the slurry results in production of a reaction product (an oxide such as an oxide film). The reaction product is, for example, an oxide of silicon (e.g., silicon dioxide). The reaction product is removed by the abrasive grains, so that the surface of the SiC wafer 40 is removed and polished. Consequently, the surface roughness of the SiC wafer 40 is reduced. Here, the reaction product resulting from the oxidation of SiC has a lower hardness than SiC. The abrasive grains of alumina, etc. contained in the slurry of this embodiment have a lower hardness than SiC, and a higher hardness than the reaction product (e.g., silicon dioxide). How to measure the hardness is not particularly limited, and for example, Vickers hardness, Mohs hardness, Knoop hardness, or the like, can be used. In this manner, the abrasive grains whose hardness is between the hardness of the reaction product and the hardness of SiC are used for the polishing step. This makes it possible to remove the reaction product produced in the SiC wafer 40 while suppressing damaging to an SiC portion of the SiC wafer 40 as well as suppressing application of a large force to the SiC wafer 40. The SiC wafer 40 in a state after the polishing step and before a work-affected layer removal step, which will be described below, can be referred to as a post-polishing SiC wafer.

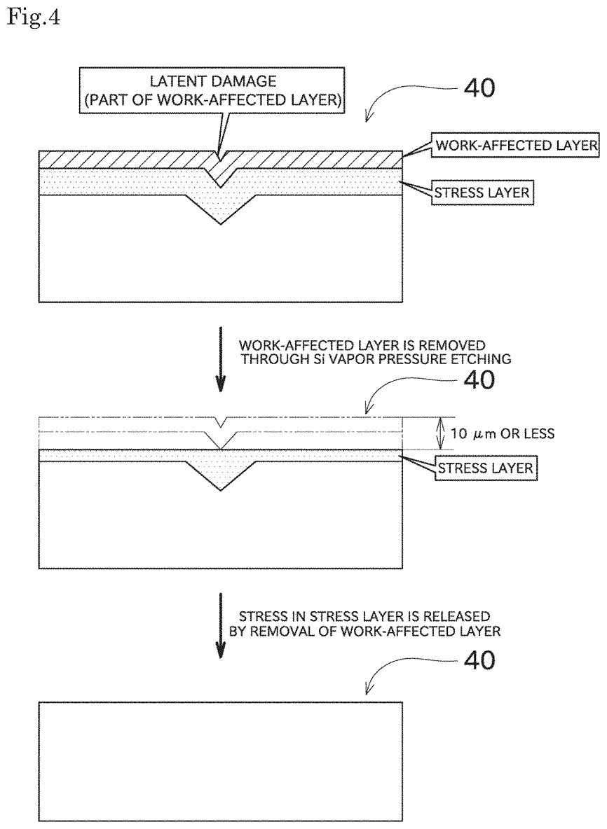

The work-affected layer removal step will now be described. Firstly, a work-affected layer generated on the SiC wafer 40 (post-polishing SiC wafer), and the like, will be described with reference to FIG. 4. FIG. 4 is a diagram illustrating that a work-affected layer and a stress layer generated on the SiC wafer 40 (post-polishing SiC wafer) are removed by the work-affected layer removal step.

As shown in FIG. 4, the SiC wafer 40 after undergoing the polishing step has a work-affected layer and a stress layer formed thereon. The work-affected layer is a region where a strain is present due to an internal stress, and where crystal breakdown or dislocation, etc. is present. The work-affected layer is caused when a force is applied to the surface and inside of the SiC wafer 40 or when the surface of the SiC wafer 40 is scratched in at least any of the wafer production step, the machining step, or the polishing step. The work-affected layer is a portion where SiC of the SiC wafer 40 is irreversibly changed (plastically deformed).

A portion of the work-affected layer containing a high degree of crystal breakdown or dislocation, etc. will be referred to as latent damage. The latent damage is characterized by existing down to the inside of the SiC wafer 40, unlike a portion of the work-affected layer such as polishing flaws existing only near the surface of the SiC wafer 40. The latent damage is also characterized by being manifested at a time of a heat treatment. To be specific, there is a case where latent damage remains inside although a microscopic observation, etc. indicates that the surface of the SiC 40 is sufficiently flat. In this case, if the SiC wafer 40 is subjected to a heat treatment (for example, Si vapor pressure etching or epitaxial layer formation which will be described later), the latent damage is manifested to cause a large surface roughness in the SiC wafer 40. To remove the latent damage having such characteristics, a large amount of portions of the SiC wafer 40 needs to be removed. In addition, it is difficult to check whether or not removal of the latent damage succeeded. This is why removal of the latent damage is more difficult than removal of other work-affected layers.

The stress layer is present farther to the inner side (the side opposite to the principal surface, or the lower side of the work-affected layer) than the work-affected layer. The stress layer, like the work-affected layer, is a portion where a strain is present due to an internal stress. The stress layer is different from the work-affected layer in that no or little crystal breakdown and dislocation is present. The cause of the stress layer is the same as the cause of the work-affected layer. More specifically, an internal stress remains in the stress layer because the work-affected layer is present due to the above-described cause. The stress layer is a portion where SiC of the SiC wafer 40 is reversibly changed (elastically deformed). Accordingly, if the work-affected layer is removed, the internal stress existing in the stress layer is released so that a state having no strain is recovered.

In this embodiment, a reaction product is produced and the reaction product is removed in the polishing step. This can suppress application of a large force to the SiC wafer 40 in the polishing step, as mentioned above. As a result, the work-affected layer and the stress layer are less easily formed, and the stress layer is formed more preferentially than the work-affected layer. This enables the work-affected layer and the stress layer to be removed with a smaller etching amount than conventional. In this embodiment, the etching amount means the amount of a portion of the principal surface of the SiC wafer 40, the portion being etched in the thickness direction (the amount of reduction in thickness, or the etching depth).

In this embodiment, the work-affected layer removal step is implemented with Si vapor pressure etching in which the SiC wafer 40 is heated under Si vapor pressure. More specifically, an SiC wafer 40 having an off-angle, for example, is received in the receiving container 30, and heated under Si vapor pressure in a temperature range of 1500° C. or more and 2200° C. or less, and desirably 1600° C. or more and 2000° C. or less by using the high-temperature vacuum furnace 10. In this heating, an inert gas in addition to Si vapor may be supplied. Supplying an inert gas can lower the etching rate at which the SiC wafer 40 is etched. Aside from Si vapor and the inert gas, another vapor source is not used. Heating the SiC wafer 40 under these conditions allows the surface to be etched while being planarized. To be specific, the reactions shown below occur. In short, if the SiC wafer 40 is heated under Si vapor pressure, SiC of the SiC wafer 40 becomes Si₂C, SiC₂, etc. due to thermal decomposition and chemical reaction with Si, and sublimates, while Si of Si atmosphere binds with C in the surface of the SiC wafer 40 to cause self-assembly, so that planarization occurs.

SiC(s)→Si(v)+C(s) (1)

2SiC(s)→Si(v)+SiC₂(v) (2)

SiC(s)+Si(v)→Si₂C(v) (3)

The Si vapor pressure etching is thermochemical etching, which is not a machining process such as grinding or polishing. The Si vapor pressure etching, therefore, does not cause generation of a work-affected layer and a stress layer. Thus, unlike machining, the Si vapor pressure etching can remove the existing work-affected layer and stress layer without newly forming another work-affected layer or another stress layer.

The uppermost part of FIG. 4 indicates the Sic wafer 40 (post-polishing wafer) after undergoing the polishing step. In this SiC wafer 40, the work-affected layer containing latent damage and the stress layer are present. In the work-affected layer removal step, Si vapor pressure etching is performed with an etching amount of 10 μm or less. It is estimated that the work-affected layer would be 10 μm or less if the polishing step according to this embodiment is performed. Accordingly, performing the work-affected layer removal step according to this embodiment can completely or almost completely remove the work-affected layer (containing the latent damage).

The middle part and the lowermost part of FIG. 4 indicate the SiC wafer 40 after undergoing the work-affected layer removal step. As described above, the stress layer is generated because of the presence of the work-affected layer, and the stress layer disappears if the work-affected layer is removed. Accordingly, by performing the work-affected layer removal step, the SiC wafer 40 having no or almost no work-affected layer and stress layer can be manufactured.

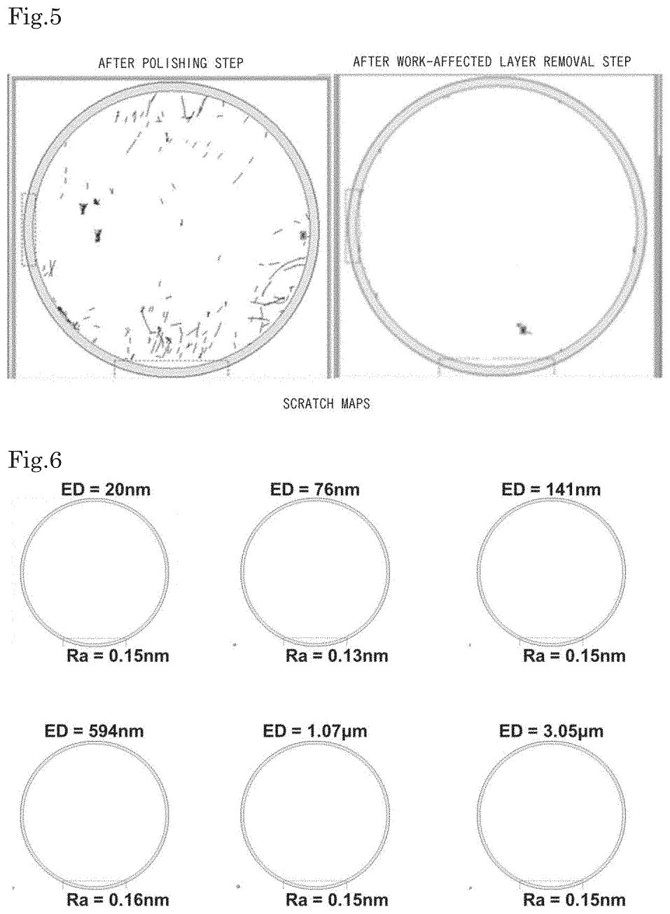

FIG. 5 shows results of experiments that were conducted to confirm that a high quality SiC wafer 40 can be obtained if a process is performed according to the method of this embodiment. In the experiments, an SiC wafer 40 obtained after the polishing step that was performed by using an alumina slurry as the slurry and an SiC wafer 40 obtained after the work-affected layer removal step that was additionally and subsequently performed with an etching amount of 3.4 μm were observed in terms of scratches in their principal surfaces. The scratch is linear damage, which is a sort of the work-affected layer.

As shown in FIG. 5, in the SiC wafer 40 obtained after the polishing step, many scratches were present. Most of many scratches were removed just by performing the etching with an etching amount of 3.4 μm. From this, it was confirmed that the SiC wafer 40 having almost no work-affected layer and stress layer can be manufactured with a considerably smaller etching amount than conventional.

Since the thickness of the work-affected layer varies depending on the conditions of the polishing step, the minimal etching amount required varies, too. As compared to the minimal etching amount required in the conventional polishing step (10 μm), the etching amount required in this embodiment is smaller. FIG. 6 shows scratch maps related to SiC wafers 40 obtained after the work-affected layer removal step. These SiC wafers 40 were etched with different etching amounts in the work-affected layer removal step. ED shown above each scratch map indicates the etching amount, and Ra shown below indicates the surface roughness (specifically, an arithmetic mean roughness Ra, hereinafter the same) obtained after the work-affected layer removal step. As shown in FIG. 6, no or almost no scratch is present in any of the scratch maps related to all the etching amounts. Thus, using the method of this embodiment enables an SiC 40 having no or almost no scratch to be manufactured just by performing the etching with the minimum etching amount of 20 nm. Considering these experimental results, the lower limit of the etching amount in the work-affected layer removal step is preferably any of 20 nm, 50 nm, 75 nm, 0.1 μm, 0.15 μm, 0.5 μm, 1 μm, 3 μm, or 5 μm for example, and the upper limit of the etching amount in the work-affected layer removal step is preferably any of 1 μm, 3 μm, 5 μm, or 10 μm for example. Using the method of this embodiment makes it possible to manufacture an SiC wafer 40 having almost no work-affected layer and stress layer with a smaller etching amount than conventional. This can shorten time required to process the SiC wafer 40, and also can reduce a load on the high-temperature vacuum furnace 10.

It is also preferable that the etching amount in the work-affected layer removal step is smaller than the removal amount in the machining step.

Then, an epitaxial layer formation step for forming an epitaxial layer 41 is performed on the principal surface of the SiC wafer 40. In the epitaxial layer formation step, the SiC wafer 40 is set in a susceptor, then the susceptor is received in a heating container, and then chemical vapor deposition (CVD) is performed. Then, a source gas, etc. is introduced under a high temperature environment, so that the epitaxial layer 41 made of monocrystalline SiC is formed on an SiC substrate. Here, the epitaxial layer 41 may be formed through another method. For example, a solution growth process such as MSE process or a close-spaced sublimation process may be adopted to form the epitaxial layer 41. The MSE process, which refers to metastable solvent epitaxy process, is a growth process using an SiC wafer, a feed substrate having a higher free energy than that of the SiC wafer, and an Si melt. The SiC wafer and the feed substrate are arranged opposed to each other with the Si melt interposed therebetween, and in this state, are heated under vacuum, so that monocrystalline SiC can be grown on a surface of the SiC wafer.

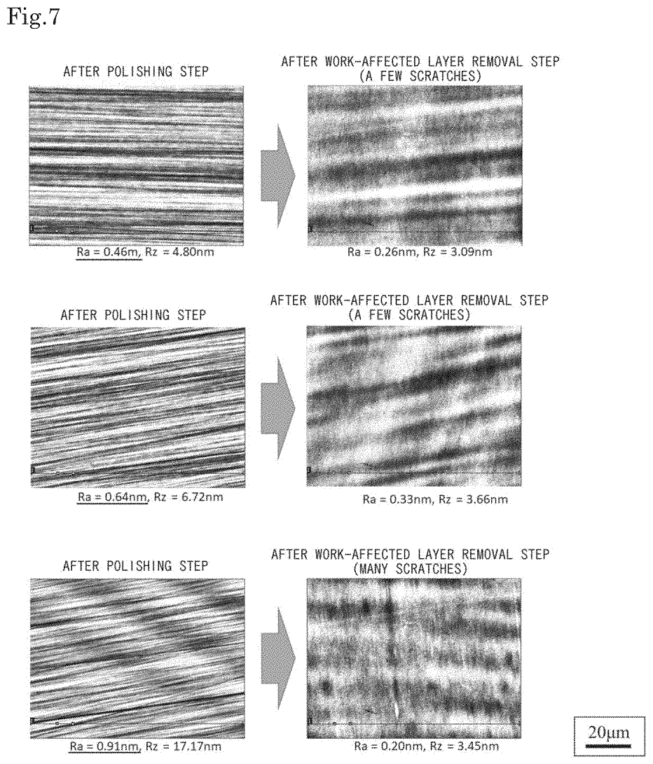

Next, with reference to FIG 7, a description will be given to experiments that were conducted to see the relationship between the surface roughness of the SiC wafer 40 after the polishing step and the scratch amount after the work-affected layer removal step performed subsequent to the polishing step.

In the experiments, three types of SiC wafers 40 having different surface roughnesses after the polishing step were prepared. The surface roughness after the polishing step varies depending on polishing conditions (the size of abrasive grains, the rotation speed of the polishing pad 52, a pressing force of the wafer carrier 55, etc.). A slurry used in the polishing step was an alumina slurry. The three types of SiC wafers 40 were subjected to the work-affected layer removal step under the same conditions. The etching amount in the work-affected layer removal step was 3.4 μm.

The two pairs of photographs shown in the uppermost and middle parts of FIG. 7 were obtained by microscopically observing SiC wafers 40 after the polishing step and the SiC wafers 40 after the work-affected layer removal step. The SiC wafers 40 after the polishing step had surface roughnesses of 0.46 nm and 0.64 nm, respectively. Scratches in surfaces of the SiC wafers 40 were expressed in the form of thin lines. In the cases where the surface roughness after the polishing step was 0.46 nm or 0.64 nm, not many scratches cannot be seen after the work-affected layer removal step. It can be seen that the SiC wafer 40 having a surface roughness of 0.46 nm after the polishing step has a slightly smaller amount of scratches after the work-affected layer removal step.

The lowermost pair of photographs shown in FIG. 7 were obtained by microscopically observing an SiC wafer 40 after the polishing step and the SiC wafer 40 after the work-affected layer removal step. The SiC wafer 40 after the polishing step had a surface roughness of 0.91 nm. The work-affected layer removal step was performed under the same conditions. In the case where the surface roughness after the polishing step was 0.91 nm, a large amount of scratches are seen after the work-affected layer removal step. In this SiC wafer 40, a large scratch is seen slightly to the left of the center with respect to the left-right direction.

From above, it can be seen that a lower surface roughness after the polishing step makes scratches less likely to occur after the work-affected layer removal step. There is a possibility that an SiC wafer 40 having a sufficiently small amount of scratches can be manufactured if the SiC wafer 40 has a surface roughness of 0.7 nm or less after the polishing step. Furthermore, an SiC wafer 40 having an even smaller amount of scratches can be manufactured if the SiC wafer 40 has a surface roughness of 0.5 nm or less after the polishing step.

As thus far described, the method for manufacturing the SiC wafer 40 according to this embodiment includes the work-affected layer removal step of removing the work-affected layer generated in the surface and inside of the SiC wafer 40, to manufacture the SiC wafer 40 from which the work-affected layer is at least partially removed. In the work-affected layer removal step, the SiC wafer 40 having undergone the polishing step is etched with an etching amount of 10 μm or less by being heated under Si vapor pressure so that the work-affected layer is removed. In the polishing step, the oxidizer is used to produce the reaction product in the SiC wafer 40 while the abrasive grains are used to remove the reaction product. In the SiC wafer 40 having undergone the polishing step, a stress caused by the work-affected layer is present at a location inner than the work-affected layer, and an internal stress of the SiC wafer 40 is reduced by removing the work-affected layer in the work-affected layer removal step.

The reaction product, which is relatively soft, produced by using the oxidizer is removed by using the abrasive grains. This makes the work-affected layer less likely to be generated, as compared to when another polishing method is adopted. Accordingly, even though the etching amount is 10 μm or less, the work-affected layer can be removed. sufficiently. In addition, the etching amount is smaller than conventional, which can shorten time required for the processing, and also can reduce a load on a processing apparatus.

In the method for manufacturing the SiC wafer 40 according to this embodiment, the surface of the SiC wafer 40 having undergone the polishing step has an arithmetic surface roughness (Ra) of 0.7 nm or less.

As the surface roughness of the SiC wafer 40 having undergone the polishing step is lower, the work-affected layer containing scratches, for example, is less likely to remain after the work-affected layer removal step which will be performed subsequent to the polishing step, and thus the SiC wafer 40 with a higher quality can be manufactured.

In the method for manufacturing the SiC wafer 40 according to this embodiment, in the work-affected layer removal step, the etching is performed with an etching amount of 5 nm or more.

This allows the work-affected layer contained in the SiC wafer 40 having undergone the polishing step to be removed sufficiently.

The method for manufacturing the SiC wafer 40 according to this embodiment further includes the polishing step that is performed before the work-affected layer removal step. In the polishing step, the oxidizer is used to produce the reaction product in the SiC wafer 40 while the abrasive grains are used to remove the reaction product, so that the surface is polished.

The reaction product, which is relatively soft, produced by using the oxidizer is removed by using the abrasive grains. This makes the work-affected layer less likely to be generated in the SiC wafer 40, as compared to when another polishing method is adopted. Accordingly, the work-affected layer can be removed easily.

In the method for manufacturing the SiC wafer 40 according to this embodiment, in the polishing step, the abrasive grains having a lower hardness than SiC are used for polishing.

Using the above-described abrasive grains can suppress damaging to an SiC portion while removing the reaction product, because the reaction product produced by using the oxidizer has a lower hardness than SiC.

While a preferred embodiment of the present invention has been described above, the configurations described above may be modified, for example, as follows.

The manufacturing steps in the foregoing embodiment are described as an example. it may be possible to change the order of the steps, to omit a part of the steps, and to add another or other steps. One example is that a step of cleaning the surface by means of hydrogen etching may be performed, for instance, before the epitaxial layer formation step.

The above-described temperature conditions and pressure conditions, etc. are merely examples, and may be changed as appropriate. In addition, it may be possible to use a heating apparatus different from the above-described high-temperature vacuum furnace 10, to use a polycrystalline SiC wafer 40, and to use a container whose shape or material is different from that of the receiving container 30. For example, the outer shape of a receiving container is not limited to a columnar shape, but instead may be a cubic shape or a rectangular parallelepiped shape.

### REFERENCE SIGNS LIST

10 high-temperature vacuum furnace

40 SiC wafer

1. A method for manufacturing an SiC wafer from which a work-affected layer is removed, the method comprising a work-affected layer removal step of removing a work-affected layer generated in a surface and inside of an SiC wafer, to manufacture an SiC wafer from which the work-affected layer is at least partially removed, wherein
in the work-affected layer removal step, a post-polishing wafer is etched with an etching amount of 10 μm or less by being heated under Si vapor pressure so that the work-affected layer is removed, the post-polishing wafer being a wafer whose surface has been polished by using an oxidizer to produce a reaction product in the SiC wafer while using abrasive grains to remove the reaction product, and
in the post-polishing wafer, a stress caused by the work-affected layer is present at a location inner than the work-affected layer, and an internal stress of the SiC wafer is reduced by removing the work-affected layer in the work-affected layer removal step.

2. The method according to claim 1 for manufacturing an SiC wafer from which a work-affected layer is removed, wherein
the surface of the post-polishing wafer has an arithmetic surface roughness (Ra) of 0.7 nm or less.

3. The method according to claim 1 for manufacturing an SiC wafer from which a work-affected layer is removed, wherein
in the work-affected layer removal step, the etching is performed with an etching amount of 20 nm or more.

4. The method according to claim 1 for manufacturing an SiC wafer from which a work-affected layer is removed, the method further comprising a polishing step that is performed before the work-affected layer removal step, wherein
in the polishing step, the oxidizer is used to produce the reaction product in the SiC wafer while the abrasive grains are used to remove the reaction product, so that a surface is polished.

5. The method according to claim 4 for manufacturing an SiC wafer from which a work-affected layer is removed, wherein
in the polishing step, the abrasive grains having a lower hardness than SiC are used for polishing.
